(19) United States
(12) Patent Application Publication
(10) Pub. No.: US 2026/0202668 A1
(43) Pub. Date: Jul. 16, 2026

(54) IMAGE DISPLAY SYSTEM

(71) Applicant: NICHIA CORPORATION, Anan-shi, Tokushima (JP)

(72) Inventors: Wataru KITAHARA, Kamiina-gun (JP); Takanori ARUGA, Suwa-gun (JP); Hajime AKIMOTO, Anan-shi (JP)

(73) Assignee: NICHIA CORPORATION, Anan-shi, Tokushima (JP)

(21) Appl. No.: 18/867,745

(22) PCT Filed: Mar. 2, 2023
(86) PCT No.: PCT/JP2023/007852

§ 371 Date: Nov. 20, 2024

(30) Foreign Application Priority Data
Jun. 3, 2022 (JP) 2022-090781

(51) Int. Cl. G02B 27/01; B60K 35/233; B60K 35/235; B60K 35/65; B60K 35/81

(52) U.S. Cl. CPC G02B 27/0101; B60K 35/233; B60K 35/235; B60K 35/654; B60K 35/81; B60K 2360/23; B60K 2360/25; B60K 2360/27; B60K 2360/31; B60K 2360/332

(57) ABSTRACT

An image display system includes: a light source unit including: a display device configured to display an image, and an imaging optical system configured to project a first image corresponding to the image toward the projection part, and to thereby display a second image, which is a virtual image visible to a viewer as being located beyond the projection part; and a drive unit configured to modify a position of the first image by controlling a position and/or an orientation of the light source unit based on a condition signal.

### CROSS-REFERENCE TO RELATED APPLICATIONS

This is a national stage of PCT Application No. PCT/JP 2023/007852, filed on Mar. 2, 2023, which claims priority to Japanese Patent Application No. 2022-090781, filed on Jun. 3, 2022.

### BACKGROUND

### Technical Field

Embodiments of the invention are related to an image display system.

### Background Art

PCT Publication No. 2016/208195 (“Patent Literature 1”) discusses technology in which light emitted from a display device configured to display an image is sequentially reflected by multiple mirrors, and the light reflected by the final mirror is further reflected toward a user by a reflecting member such as a windshield or the like, so that the user views a virtual image corresponding to the image displayed by the display device. However, in the technology discussed in Patent Literature 1, the position of the virtual image when viewed by the user is fixed.

### SUMMARY

Embodiments of the invention are directed to provide an image display system in which the position of a virtual image can be modified.

An image display system according to an embodiment of the invention, includes a light source unit and a drive unit. The light source unit includes a display device and an imaging optical system. The display device is capable of displaying an image. The imaging optical system is configured to display an image visible to a viewer beyond a projection part when viewed by the viewer by projecting a first image corresponding to the image toward the projection part. The image is visible to the viewer. The drive unit modifies a position of the first image by controlling a position and/or an orientation of the light source unit based on a condition signal input from outside.

According to embodiments of the invention, an image display system can be achieved in which the position of a virtual image can be modified.

### BRIEF DESCRIPTION OF THE DRAWINGS

FIG. 1 is a top view showing an image display system according to a first embodiment.

FIG. 2 is an end view showing the image display system according to the first embodiment.

FIG. 3 is an end view showing the display device of the image display system according to the first embodiment.

FIG. 4 is a schematic view showing a scenery when viewed by a viewer in a driver's seat.

FIG. 5 is a drawing showing content displayed by the image display system according to the first embodiment.

FIG. 6A is a schematic view showing the principle of the light source unit according to the first embodiment.

FIG. 6B is a schematic view showing the principle of a light source unit according to a reference example.

FIG. 7A is a graph showing a light distribution pattern of light emitted from one light-emitting area for examples 1 and 11, the reference example, and an LCD.

FIG. 7B is a graph showing the uniformity of the luminance of the second image for the examples 1 to 12 and the reference example.

FIG. 8 is a top view showing an image display system according to a second embodiment.

FIG. 9 is an end view showing the image display system according to the second embodiment.

FIG. 10 is a schematic view showing a scenery when viewed by a viewer in a driver's seat.

FIG. 11 is an end view showing an image display system according to a third embodiment.

FIG. 12 is an enlarged cross-sectional view showing a portion of the display device and the reflective polarizing element shown in FIG. 11.

FIG. 13 is an end view showing a display device according to a modification of the third embodiment.

FIG. 14 is a perspective view showing a reflective polarizing element according to the modification of the third embodiment.

FIG. 15 is a side view showing a light source unit according to a fourth embodiment.

FIG. 16 is a side view showing a light source unit according to a modification of the fourth embodiment.

### DETAILED DESCRIPTION

Embodiments and their modifications will now be described with reference to the drawings. The drawings are schematic or conceptual, and are enhanced or simplified as appropriate. For example, the relationships between the thickness and width of portions, the proportions of sizes among portions, etc., are not necessarily the same as the actual values. Also, the dimensions and proportions may be illustrated differently among drawings, even when the same portion is illustrated. Furthermore, in the specification and the drawings, components similar to those described in regard to an antecedent drawing are marked with the same reference numerals; and a detailed description is omitted as appropriate.

### First Embodiment

First, a first embodiment will be described.

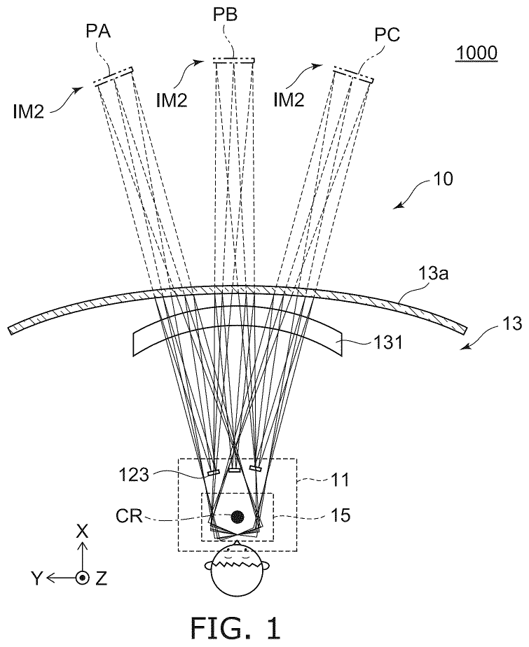

FIG. 1 is a top view showing an image display system according to the embodiment.

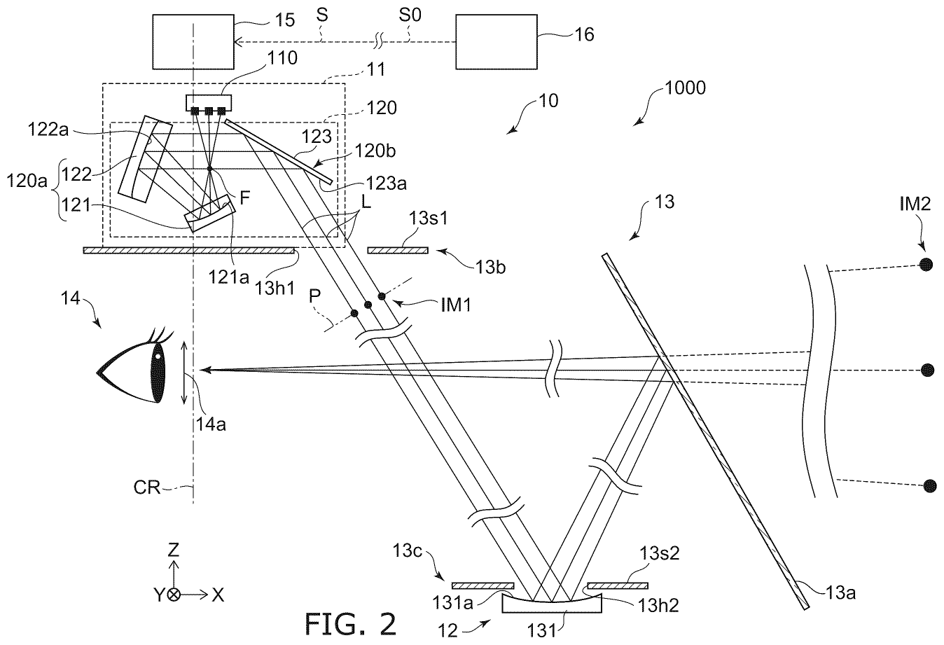

FIG. 2 is an end view showing the image display system according to the embodiment.

As shown in FIGS. 1 and 2, the image display system 10 according to the embodiment includes a light source unit 11, a reflection unit 12, and a drive unit 15. The light source unit 11 includes a display device 110 and an imaging optical system 120. The display device 110 is capable of displaying an image. The imaging optical system 120 projects a first image IM1 corresponding to the image displayed by the display device 110 toward a projection part, which is described below, thereby displaying a second image IM2, which is visible to a viewer 14, beyond the projection part when viewed by the viewer 14. According to the embodiment, the projection part is a front windshield 13a of a vehicle 13. However, the projection part may be a combiner. The drive unit 15 modifies the position of the first image IM1 by controlling the position and/or orientation of the light source unit 11 based on a condition signal S input from outside. The first image IM1 is a real image, and is an intermediate image. The second image IM2 is a virtual image that is larger than the first image IM1.

Specifically, for example, the image display system 10 is mounted in an automobile 1000, and is included in a HUD (Head Up Display). The automobile 1000 includes the vehicle 13, a condition detecting part 16 that detects a condition inside and/or outside the vehicle 13 and outputs the detection result, and the image display system 10 fixed to the vehicle 13. The viewer 14 is an occupant of the automobile 1000, and is, for example, a driver.

The display device 110 of the light source unit 11 displays an image to be viewed by the viewer 14 with the HUD. The image is character strings and/or figures, etc. Specific examples of the display device 110 and the image are described below. The imaging optical system 120 of the light source unit 11 outputs the light emitted from the display device 110 toward the reflection unit 12 and forms the first image IM1 between the light source unit 11 and the reflection unit 12. The reflection unit 12 reflects the light emitted from the light source unit 11 toward the front windshield 13a of the vehicle 13. The front windshield 13a includes, for example, glass.

The inner surface of the front windshield 13a reflects the light from the reflection unit 12 and causes the light to enter an eyebox 14a of the viewer 14. As a result, the viewer 14 can view the second image IM2 corresponding to the image displayed by the display device 110. “Eyebox” refers to the area of space in front of the eyes of the viewer where the virtual image is visible.

The condition detecting part 16 is, for example, an adaptive front-lighting system (Adaptive Front-Lighting System: AFS). The AFS is a system that detects the rotation amount of the steering wheel of the vehicle 13, and based on the rotation amount, directs the optical axis of a headlight in the travel direction of the vehicle 13 when cornering. In such a case, an output signal S0 of the condition detecting part 16 indicates the travel direction of the vehicle 13. Also, the condition detecting part 16 may be, for example, an eye tracking system that detects the direction of the line of sight of the viewer 14. In such a case, the output signal S0 indicates the direction of the line of sight of the viewer 14. Also, the condition detecting part 16 may be, for example, an external sensor that detects objects outside the vehicle 13. Objects outside are, for example, pedestrians jumping out into the road, or other vehicles. In such a case, the output signal S0 indicates the direction from the vehicle 13 toward the object outside the vehicle 13.

The condition detecting part 16 is not limited to the example above as long as the condition detecting part 16 detects a condition inside or outside the vehicle 13 and outputs the detection result as the output signal S0. Also, the condition detecting part 16 may include multiple detection means. For example, the condition detecting part 16 may include two or all of an AFS, an eye tracking system, or an external sensor.

The condition signal S that is based on the output signal S0 of the condition detecting part 16 is input to the drive unit 15. The condition signal S may be directly input from the condition detecting part 16 to the drive unit 15, or may be input via an on-board computer, etc. When the condition signal S is directly input from the condition detecting part 16, the output signal S0 of the condition detecting part 16 is the condition signal S. When the condition signal S is input via an on-board computer or the like, there are cases where the condition signal S and the output signal S0 have different formats, rates, ancillary information, etc.; however, the information that is transmitted is related. Also, when the condition detecting part 16 includes multiple detection means, the on-board computer may generate the condition signal S by comprehensively determining the content of multiple output signals S0.

The drive unit 15 controls the position and/or orientation of the light source unit 11 based on the condition signal S. For example, based on the condition signal S, the drive unit 15 controls the orientation of the light source unit 11 with an axis CR as the rotation axis. It is preferable for the axis CR to extend in the vertical direction of the vehicle 13 and to pass through the eyebox 14a of the viewer 14 or the vicinity of the eyebox 14a. It is more preferable for the axis CR to match the axis of the eyebox 14a. The drive unit 15 includes, for example, a stepper motor. The drive unit 15 modifies the position of the first image IM1 by controlling the orientation of the light source unit 11.

For example, when the condition detecting part 16 is an AFS, and the condition signal S indicates the travel direction of the vehicle 13, the drive unit 15 sets the direction in which the light source unit 11 projects the first image IM1 (hereinbelow, called the “emission direction”) to a direction corresponding to the travel direction of the vehicle 13. Also, when the condition detecting part 16 is an eye tracking system, and the condition signal S indicates the direction of the line of sight of the viewer 14, the drive unit 15 sets the emission direction to a direction corresponding to the direction of the line of sight. Also, when the condition detecting part 16 is an external sensor, and the condition signal S indicates a direction from the vehicle 13 toward an object outside the vehicle 13, the drive unit 15 sets the emission direction to a direction corresponding to the direction toward the object.

For example, the drive unit 15 selects one from among three locations as the position of the first image IM1. The reflection unit 12 and the front windshield 13a are capable of reflecting the light emitted from the light source unit 11 toward the eyebox 14a of the viewer 14 when the first image IM1 is at any position. As a result, the position of the second image IM2 viewed by the viewer 14 changes conjunctively with the position of the first image IM1. As a result, when viewed by the viewer 14, the position at which the second image IM2 can be seen is selected from, for example, the three locations of positions PA, PB, and PC. For example, when viewed by the viewer 14, the position PA is at the front left, the position PB is at the front, and the position PC is at the front right. The positions at which the second image IM2 can be displayed is not limited to three locations and may be two locations, four locations, or more. Also, the arrangement of the displayable positions may have uniform spacing, but does not have to have uniform spacing.

A detailed structure of the image display system 10 will now be described.

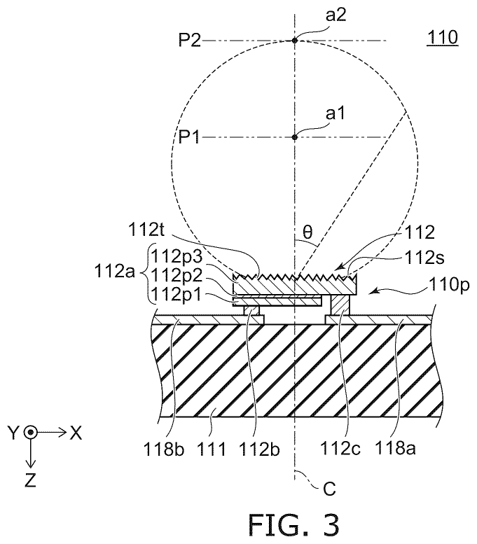

FIG. 3 is an end view showing the display device of the image display system according to the embodiment.

Hereinbelow, the arrangements and configurations of the portions are described using an XYZ orthogonal coordinate system for easier understanding of the description. According to the embodiment, the longitudinal direction of the vehicle 13 is taken as an “X-direction”; the lateral direction of the vehicle 13 is taken as a “Y-direction”; and the vertical direction of the vehicle 13 is taken as a “Z-direction”. The XY-plane is the horizontal plane of the vehicle 13. The direction of the arrow in the X-direction (front) also is called the “+X direction”, and the opposite direction (back) also is called the “−X direction”. The direction of the arrow in the Y-direction (left) also is called the “+Y direction”, and the opposite direction (right) also is called the “−Y direction”. The direction of the arrow in the Z-direction (up/above) also is called the “+Z direction”, and the opposite direction (down/below) also is called the “−Z direction”.

Also, in FIG. 2, the position at which the first image IM1 is formed is illustrated by circular marks. Also, similarly to the first image IM1, the position at which the second image IM2 is formed is illustrated by circular marks. On the other hand, the emission positions in the display device 110 of principal rays L that reach the marks of the first image IM1 are illustrated by quadrilateral marks. Thus, although the marks used to illustrate the emission positions on the display device 110 of the principal rays L are different from those of the image formation position of the first image IM1 and the formation position of the second image IM2 for easier understanding of the description, the image displayed on the display device 110, the first image IM1, and the second image IM2 have substantially similar relationships.

### Light Source Unit

The display device 110 of the light source unit 11 is an LED display. The multiple LED elements 112 are arranged in a matrix configuration in the display device 110. One or multiple LED elements 112 correspond to each pixel of the display device 110.

In the display device 110 as shown in FIG. 3, each LED element 112 is mounted face-down on a substrate 111. However, each LED element may be mounted face-up on the substrate. Each LED element 112 includes a semiconductor stacked body 112a, an anode electrode 112b, and a cathode electrode 112c.

The semiconductor stacked body 112a includes a p-type semiconductor layer 112p1, an active layer 112p2 located on the p-type semiconductor layer 112p1, and an n-type semiconductor layer 112p3 located on the active layer 112p2. The semiconductor stacked body 112a includes, for example, a gallium nitride compound semiconductor of InₓAl_{y}Ga_{1-X-Y}N (0≤X, 0≤Y, and X+Y<1). According to the embodiment, the light that is emitted by the LED element 112 is visible light.

The anode electrode 112b is electrically connected to the p-type semiconductor layer 112p1. Also, the anode electrode 112b is electrically connected to a wiring part 118b. The cathode electrode 112c is electrically connected to the n-type semiconductor layer 112p3. Also, the cathode electrode 112c is electrically connected to another wiring part 118a. The electrodes 112b and 112c can include, for example, a metal material.

According to the embodiment, multiple recessed portions 112t are provided in a light-emitting surface 112s of each LED element 112. In the specification, “the light-emitting surface of the LED element” means the surface of the LED element that mainly emits the light that is incident on the imaging optical system 120. According to the embodiment, the surface of the n-type semiconductor layer 112p3 that is positioned at the side opposite to the surface facing the active layer 112p2 corresponds to the light-emitting surface 112s.

Hereinbelow, the optical axis of the light emitted from each pixel 110p is called simply an “optical axis C”. The optical axis C is, for example, a straight line that connects a point a1 in a first plane P1 and a point a2 in a second plane P2, wherein the first plane P1 is positioned at the light-emitting side of the display device 110 and is parallel to the XY-plane in which the multiple pixels 110p are arranged; the luminance has a maximum at the point a1 in the range in which the light is irradiated from one pixel 110p; the second plane P2 is parallel to the XY-plane and spaced apart from the first plane P1; and the luminance has a maximum at the point a2 in the range in which the light is irradiated from the one pixel 110p. For example, if the luminance has maxima at multiple points, the center of the points may be used as the maximum luminance point. From the perspective of productivity, it is desirable for the optical axis C to be parallel to the Z-axis.

By providing the multiple recessed portions 112t in the light-emitting surface 112s of each LED element 112, the light that is emitted from each LED element 112, i.e., the light that is emitted from each pixel 110p, has a substantially Lambertian light distribution as illustrated by the broken line in FIG. 3. Here, “the light emitted from each pixel has a substantially Lambertian light distribution” means a light distribution pattern in which the luminous intensity in the direction of an angle θ with respect to the optical axis C of each pixel can be approximated by cosⁿθ times the luminous intensity at the optical axis C, wherein n is a value greater than 0. Here, it is preferable for n to be not more than 11, and more preferably 1. Although many planes including the optical axis C of the light emitted from one pixel 110p exist, the light distribution pattern of the light emitted from the one pixel 110p has a substantially Lambertian light distribution in each plane, and the numerical values of n are substantially equal.

As shown in FIG. 2, the imaging optical system 120 of the light source unit 11 is an optical system that includes all of the optical elements necessary for forming the first image IM1 at the predetermined position. The embodiment includes an input element 121 on which the light emitted from the display device 110 is incident, an intermediate element 122 on which the light reflected by the input element 121 is incident, and an output element 123 on which the light reflected by the intermediate element 122 is incident. The light that is emitted from the output element 123 forms the first image IM1. It is sufficient for the light traveling via the input element 121 to be incident on the output element 123, and the intermediate element 122 does not have to be included.

The imaging optical system 120 is substantially telecentric at the first image IM1 side. Here, “the imaging optical system 120 is substantially telecentric at the first image IM1 side” means that the multiple principal rays L that are emitted from mutually-different positions of the display device 110, travel via the imaging optical system 120, and reach the first image IM1 are substantially parallel to each other before and after the first image IM1 as shown in FIG. 2. “Different positions” refers to, for example, different pixels 110p of the display device 110. “The multiple principal rays L being substantially parallel to each other” means being substantially parallel in a practical range that permits tolerances due to the manufacturing accuracy, assembly accuracy, etc., of the components of the light source unit 11. When “the multiple principal rays L are substantially parallel to each other”, for example, the angle between the principal rays L is not more than 10 degrees.

When the imaging optical system 120 is substantially telecentric at the first image IM1 side, the multiple principal rays L cross each other before being incident on the input element 121. Hereinbelow, the point at which the multiple principal rays L cross each other is called a “focal point F”. Therefore, for example, whether or not the imaging optical system 120 is substantially telecentric at the first image IM1 side can be confirmed by utilizing the backward propagation of light by the following method. First, a light source such as a laser light source or the like that can emit parallel light is disposed at the vicinity of the position at which the first image IM1 is formed. The light that is emitted from the light source is irradiated on the output element 123 of the imaging optical system 120. The light that is emitted from the light source and travels via the output element 123 is incident on the input element 121. Then, if the light that is emitted from the input element 121 condenses at a point, i.e., the focal point F, before reaching the display device 110, then the imaging optical system 120 can be determined to be substantially telecentric at the first image IM1 side.

Because the imaging optical system 120 is substantially telecentric at the first image IM1 side, the light emitted from each pixel of the display device 110 that is mainly incident on the imaging optical system 120 is the light that passes through the focal point F and the vicinity of the focal point F. Optical elements included in the imaging optical system 120 will now be described.

The input element 121 is positioned at the −Z side in the display device 110 and arranged to face the display device 110. The input element 121 is a mirror that includes a concave mirror surface 121a. The input element 121 reflects the light emitted from the display device 110.

The intermediate element 122 is positioned at the-X side than the display device 110 and the input element 121 and arranged to face the input element 121. The intermediate element 122 is a mirror that includes a concave mirror surface 122a. The intermediate element 122 further reflects the light reflected by the input element 121.

The input element 121 and the intermediate element 122 are included in a bending part 120a that bends the multiple principal rays L so that the multiple principal rays L emitted from mutually-different positions of the display device 110 are substantially parallel to each other. According to the embodiment, the mirror surfaces 121a and 122a are biconic surfaces. However, the mirror surfaces may be portions of spherical surfaces or may be freeform surfaces.

The output element 123 is positioned at the +X side of the display device 110 and the input element 121 and arranged to face the intermediate element 122. The output element 123 is a mirror that includes a flat mirror surface 123a. The output element 123 reflects the light traveling via the input element 121 and the intermediate element 122 toward the formation position of the first image IM1. Specifically, the multiple principal rays L that are substantially parallel due to the bending part 120a are incident on the output element 123. The mirror surface 123a is tilted in the +X/−Z direction with respect to the XY-plane, i.e., the horizontal plane of the vehicle 13. As a result, the light that is reflected by the intermediate element 122 is reflected by the output element 123 in a direction tilted in the +X/−Z direction with respect to the Z-direction. As shown in FIG. 2, the output element 123 is included in a direction modifying part 120b that modifies the directions of the multiple principal rays L so that the multiple principal rays L caused to be substantially parallel by the bending part 120a are directed toward a formation position P of the first image IM1.

According to the embodiment, the optical path between the input element 121 and the intermediate element 122 extends in a direction crossing the XY-plane. Also, the optical path between the intermediate element 122 and the output element 123 extends in a direction along the XY-plane. Because a portion of the optical path in the imaging optical system 120 extends in a direction crossing the XY-plane, the light source unit 11 can be smaller in directions along the XY-plane. Also, because another portion of the optical path inside the imaging optical system 120 extends in a direction along the XY-plane, the light source unit 11 can be smaller in the Z-direction.

Also, the optical path between the display device 110 and the input element 121 crosses the optical path between the intermediate element 122 and the output element 123. Thus, by causing the optical paths to cross each other in the light source unit 11, the light source unit 11 can be smaller.

However, the optical paths in the light source unit are not limited to those described above. For example, all of the optical paths in the imaging optical system may extend in directions along the XY-plane or may extend in directions crossing the XY-plane. Also, the optical paths in the light source unit may not cross each other.

The input element 121, the intermediate element 122, and the output element 123 each may include a base member formed of glass, a resin material, or the like and a reflective film such as a metal film, a dielectric multilayer film, or the like forming the mirror surfaces 121a, 122a, and 123a located at the surface of the base member. Also, the input element 121, the intermediate element 122, and the output element 123 each may be entirely formed of a metal material.

According to the embodiment as shown in FIG. 2, the light source unit 11 is located at a ceiling part 13b of the vehicle 13. For example, the light source unit 11 is located at the inner side of a wall 13s1 of the ceiling part 13b exposed inside the vehicle. A through-hole 13h1 through which the light emitted from the output element 123 of the light source unit 11 can pass is provided in the wall 13s1. The light that is emitted from the output element 123 passes through the through-hole 13h1 and is irradiated on the space between the viewer 14 and the front windshield 13a. However, the light source unit may be mounted to the ceiling surface. A transparent or semi-transparent cover having a small haze (Haze) value may be located in the through-hole 13h1. Including the cover can suppress the adhesion of dust, etc., to the optical unit. Including the cover can also suppress the light source unit from being viewed through the through-hole 13h1, and the designability can be improved. It is preferable for the haze value to be not more than 50%, and more preferably not more than 20%. By the cover having such a haze value, the effects described above can be obtained while suppressing a drastic reduction of the luminance of the light emitted from the light source unit 11 and a disturbance of the image.

Although the imaging optical system 120 is described above, the configuration and position of the imaging optical system are not limited to those described above as long as the imaging optical system is substantially telecentric at the first image side. For example, the number of optical elements included in the direction modifying part may be two or more.

### Reflection Unit

According to the embodiment as shown in FIG. 2, the reflection unit 12 includes a mirror 131 that includes a concave mirror surface 131a. The mirror 131 is arranged to face the front windshield 13a. The mirror 131 reflects the light emitted from the output element 123 and irradiates the light on the front windshield 13a. The mirror 131 may include a base member formed of glass, a resin material, or the like and a reflective film such as a metal film, a dielectric multilayer film, or the like forming the mirror surface 131a located at the surface of the base member. Also, the mirror 131 may be entirely formed of a metal material.

The mirror 131 is arranged so that the light emitted from the light source unit 11 is incident even when the drive unit 15 changes the orientation of the light source unit 11. The mirror 131 may be provided as separate bodies according to the positions PA, PB, and PC of the second image IM2, or may be provided as one piece. The curvature of the mirror surface 131a of the mirror 131 is set according to the positions PA, PB, and PC of the second image IM2. The mirror surface 131a may be a continuous curved surface. Alternatively, the mirror surface 131a may be divided into the three regions corresponding to the positions PA, PB, and PC of the second image IM2, and boundaries may be formed between the regions. In an example, the mirror surface 131a is a biconic surface. However, the mirror surface may be a portion of a spherical surface, or may be a freeform surface.

The light that is irradiated on the front windshield 13a is reflected by the inner surface of the front windshield 13a and enters the eyebox 14a of the viewer 14. As a result, the viewer 14 views, at the positions PA, PB, or PC beyond the front windshield 13a, the second image IM2 corresponding to the image displayed in the display device 110.

According to the embodiment, the reflection unit 12 is located at a dashboard part 13c of the vehicle 13. For example, the reflection unit 12 is located at the inner side of a wall 13s2 of the dashboard part 13c of the vehicle 13 exposed inside the vehicle. A through-hole 13h2 through which the light emitted from the output element 123 of the light source unit 11 can pass is provided in the wall 13s2. The light that is emitted from the output element 123 passes through the through-hole 13h1, forms the first image IM1, subsequently passes through the through-hole 13h2, and is irradiated on the reflection unit 12. However, the reflection unit may be mounted to the upper surface of the dashboard part. Also, the reflection unit may be located at the ceiling part; and the light source unit may be located at the dashboard part.

In the example shown in FIG. 2, the path of the light from the inner surface of the front windshield 13a toward the eyebox 14a is substantially horizontal. In other words, the path is substantially parallel to the XY-plane. Also, according to the embodiment, when referenced to the XY-plane including this path of the light, the light source unit 11 is located above (the +Z direction), and the reflection unit 12 is located below (the −Z direction). In other words, the light source unit 11 and the reflection unit 12 are separated with this XY-plane interposed. However, the path of the light from the inner surface of the front windshield 13a toward the eyebox 14a may not be substantially horizontal, and may be tilted.

Although the reflection unit 12 is described above, the configuration and position of the reflection unit are not limited to those described above. For example, the number of optical elements such as mirrors and the like included in the reflection unit may be two or more. The reflection unit 12 must be arranged so that, for example, sunlight that is irradiated from outside the vehicle via the front windshield 13a is not reflected toward the eyebox 14a.

Operations of the image display system 10 according to the embodiment will now be described.

First, an operation of switching the display positions of the second image IM2 will be described.

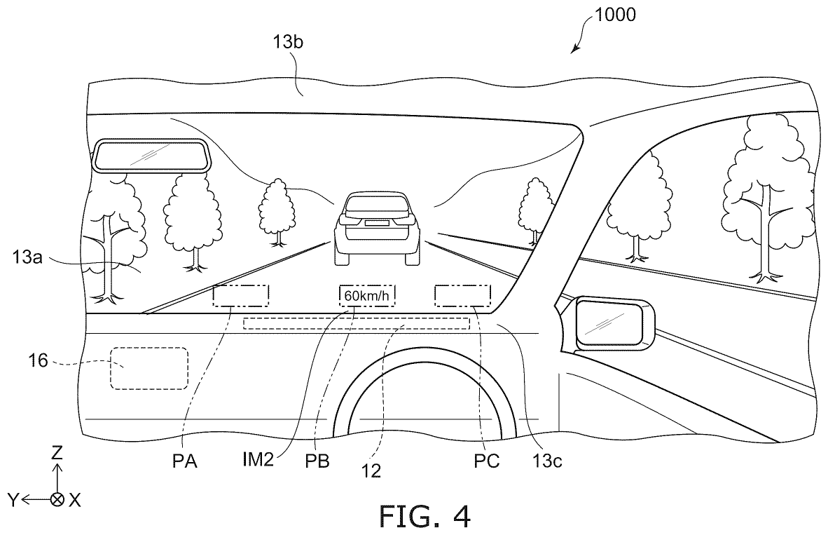

FIG. 4 is a schematic view showing a scenery when viewed by a viewer in a driver's seat.

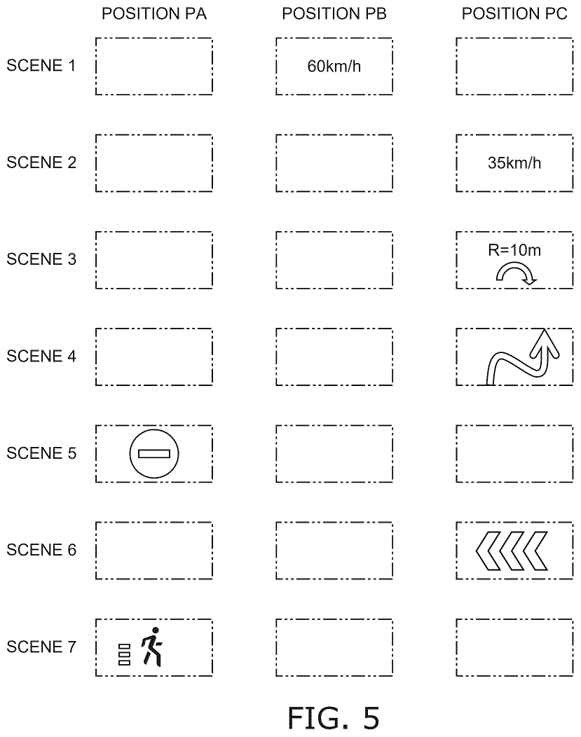

FIG. 5 is a drawing showing content displayed by the image display system according to the embodiment.

As shown in FIGS. 1 to 3, the condition detecting part 16 detects a condition inside and/or outside the vehicle 13 and outputs the output signal S0. The output signal S0 is used as the condition signal S as-is, or the condition signal S is generated based on the output signal S0, and then the condition signal S is input to the drive unit 15. The drive unit 15 controls the orientation of the light source unit 11 based on the condition signal S. In this state, the display device 110 of the light source unit 11 displays an image. Based on the image, the imaging optical system 120 of the light source unit 11 forms the first image IM1, which is a real image, at the position P. Then, the light that formed the first image IM1 is reflected by the reflection unit 12 and the front windshield 13a and enters the eyebox 14a of the viewer 14. As a result, the viewer 14 views the second image IM2, which is a virtual image.

At this time, the position at which the first image IM1 is formed changes substantially along the XY-plane according to the orientation of the light source unit 11. According to the embodiment, for example, the position is selected from three locations. As a result, the position at which the viewer 14 views the second image IM2 also changes. According to the embodiment, one is selected from the positions PA, PB, and PC as the position at which the viewer 14 views the second image IM2.

Examples of the display content will now be described.

The image display system 10 may display information of the traveling state of the automobile 1000, e.g., the speed.

When the automobile 1000 is traveling straight as shown in a scene 1 of FIG. 5, the image display system 10 displays the speed at the position PB corresponding to the front of the viewer 14. At this time, nothing is displayed at the positions PA and PC.

When the viewer 14, which is the driver, steers the steering wheel rightward as shown in a scene 2 of FIG. 5, the AFS of the condition detecting part 16 detects the steering, and the image display system 10 switches the display to the position PC positioned frontward and rightward of the viewer 14. The eye tracking system of the condition detecting part 16 may switch the display position by detecting the direction of the line of sight of the viewer 14.

Also, the image display system 10 may display navigation information, e.g., the curvature radius (R) of a corner or a road condition beyond the corner. The navigation information can be acquired from a navigation system.

When cornering rightward as shown in a scene 3 of FIG. 5, the image display system 10 may display a curvature radius (R) of a corner at the position PC. Also, based on the speed and the curvature radius, a warning of being too fast may be displayed.

When cornering rightward as shown in a scene 4 of FIG. 5, the image display system 10 may display that there is a left corner after a right corner.

When the viewer 14 attempts to turn left as shown in a scene 5 of FIG. 5, the image display system 10 may display that the road to the left is no-entry.

The image display system 10 also may draw attention to a condition outside the vehicle, e.g., a pedestrian that jumped out, or another vehicle trying to overtake.

As shown in a scene 6 of FIG. 5, when the viewer 14 views the right side, when a pedestrian jumps out from the left side, or when another vehicle is trying to overtake from the left side, the external sensor of the condition detecting part 16 detects such a condition, and the image display system 10 displays, at the position PC within the visual field of the viewer 14, that caution is needed at the left side. Continuing as shown in the scene 7, content that caution is needed may be displayed at the position PA positioned frontward and leftward of the viewer 14. The line of sight of the viewer 14 can be directed thereby. When it is determined that it is dangerous to direct the line of sight of the viewer 14, the content to be given attention may be displayed at the position PC, and nothing may be displayed at the position PA.

Effects of the embodiment will now be described.

According to the embodiment, the drive unit 15 is capable of modifying the position of the virtual image (the second image IM2) by controlling the orientation of the light source unit 11 based on the condition signal S. As a result, the operation of the automobile by the viewer 14 can be effectively supported.

Also, according to the embodiment, the imaging optical system 120 is substantially telecentric at the first image IM1 side, and so a compact and high-quality image can be displayed. This effect will now be described in detail.

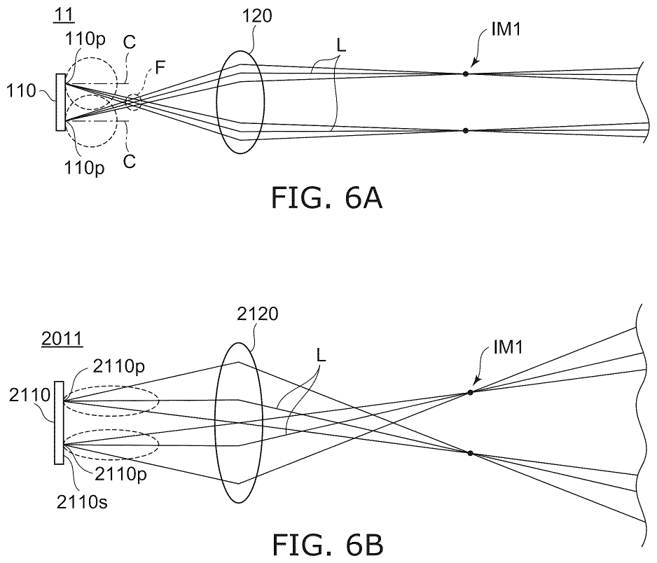

FIG. 6A is a schematic view showing the principle of the light source unit according to the embodiment.

FIG. 6B is a schematic view showing the principle of a light source unit according to a reference example.

In FIG. 6A, the light distribution patterns of light emitted from two pixels 110p among the multiple pixels 110p of the display device 110 according to the embodiment are illustrated by broken lines. Similarly, in FIG. 6B, the light distribution patterns of light emitted from two pixels 2110p among the multiple pixels 2110p of a display device 2110 according to the reference example are illustrated by broken lines. Also, the imaging optical systems 120 and 2120 are simplified in FIGS. 6A and 6B.

In a light source unit 2011 according to the reference example as shown in FIG. 6B, the display device 2110 is a liquid crystal display device (Liquid Crystal Display: LCD) that includes the multiple pixels 2110p. As illustrated by the broken lines in FIG. 6B, the light that is emitted from each pixel 2110p is mainly distributed in the normal direction of a light-emitting surface 2110s. Although many planes that include the optical axis of the light emitted from one pixel 2110p exist, in the display device 2110 which is an LCD, the light distribution patterns of the light emitted from one pixel 2110p are different from each other between the planes. Also, in one plane among the multiple planes, the light that is emitted from the pixels 2110p has a light distribution pattern in which the luminous intensity in the direction of the angle θ with respect to the optical axis is approximated by cos²⁰θ times the luminous intensity at the optical axis.

In such a display device 2110, the luminous intensity and/or chromaticity changes according to the viewing angle of the viewer, even when the light is emitted from the same position of the display device 2110. Accordingly, even when the luminance of the light emitted from all of the pixels 2110p is uniform, the luminance and/or chromaticity of the first image IM1 fluctuate if the imaging optical system 2120 receives the light emitted from the pixels 2110p from directions other than the normal direction. In other words, the quality of the first image IM1 degrades. Accordingly, to prevent degradation of the quality of the first image IM1, it is necessary to receive the light emitted from each pixel 2110p of the display device 2110 from the normal direction. As a result, the imaging optical system 2120 is larger.

In contrast, in the light source unit 11 according to the embodiment, the imaging optical system 120 is substantially telecentric at the first image IM1 side, and the light that is emitted from the display device 110 has a substantially Lambertian light distribution. Therefore, the quality of the first image IM1 can be improved while making the light source unit 11 smaller. Specifically, the display device 110 is an LED display including the multiple LED elements 112, and the light that is emitted from each LED element 112 has a substantially Lambertian light distribution. Therefore, the dependence on the angle of the luminous intensity and/or chromaticity of the light emitted from the pixels 110p of the display device 110 is less than the dependence on the angle of the luminous intensity and/or chromaticity of the light emitted from the pixels 2110p of the display device 2110 according to the reference example. In particular, as an exact Lambertian light distribution is approached, that is, as n in the approximation formula of the light distribution pattern, cosⁿθ, approaches 1, the luminous intensity and/or chromaticity of the light emitted from each pixel 110p of the display device 110 is substantially uniform regardless of the angle. Therefore, as shown in FIG. 6A, even when the imaging optical system 120 receives light passing through the focal point F, that is, light from a direction other than the normal direction, the variation of the luminance and/or chromaticity of the first image IM1 can be suppressed, and the quality of the first image IM1 can be improved.

Also, because the imaging optical system 120 forms the first image IM1 by mainly using light passing through the focal point F, an increase of the light diameter of the light incident on the imaging optical system 120 can be suppressed. The input element 121 can be smaller thereby. Also, the multiple principal rays L that are emitted from the output element 123 are substantially parallel to each other. The multiple principal rays L emitted from the output element 123 being substantially parallel to each other means that the irradiation range of the light of the output element 123 contributing to the image formation is substantially equal to the size of the first image IM1. Therefore, the output element 123 of the imaging optical system 120 also can be smaller. Thus, the light source unit 11 that is compact and can form a high-quality first image IM1 can be provided.

Also, the image display system 10 according to the embodiment includes the light source unit 11, and the reflection unit 12 that is separated from the light source unit 11 and reflects the light emitted from the imaging optical system 120. The first image IM1 is formed between the light source unit 11 and the reflection unit 12. In such a case, the light that is emitted from one point of the display device 110 is condensed at the formation position of the first image IM1 after traveling via the output element 123. On the other hand, when the first image IM1 is not formed between the light source unit 11 and the reflection unit 12, the light diameter of the light emitted from one point of the display device 110 gradually spreads from the input element 121 toward the reflection unit 12. Accordingly, in the output element 123 according to the embodiment, the irradiation range of the light emitted from one point of the display device 110 can be less than when the first image IM1 is not formed. Therefore, the output element 123 can be smaller.

Also, because the light source unit 11 according to the embodiment is compact, the light source unit 11 can be easily located in the limited space inside the vehicle 13 when the light source unit 11 is mounted in the vehicle 13 and used as a head-up display.

Also, according to the embodiment, the imaging optical system 120 includes the bending part 120a and the direction modifying part 120b. Thus, the design of the imaging optical system 120 is easier because the part of the imaging optical system 120 having the function of making the principal rays L parallel to each other and the part of the imaging optical system 120 forming the first image IM1 at the desired position are separate.

Also, a portion of the optical path in the imaging optical system 120 extends in a direction crossing the XY-plane. Therefore, the imaging optical system 120 can be smaller in directions along the XY-plane. Also, another portion of the optical path in the imaging optical system 120 extends in a direction along the XY-plane. Therefore, the imaging optical system 120 can be smaller in the Z-direction.

### Examples

Light source units according to examples and a reference example will now be described.

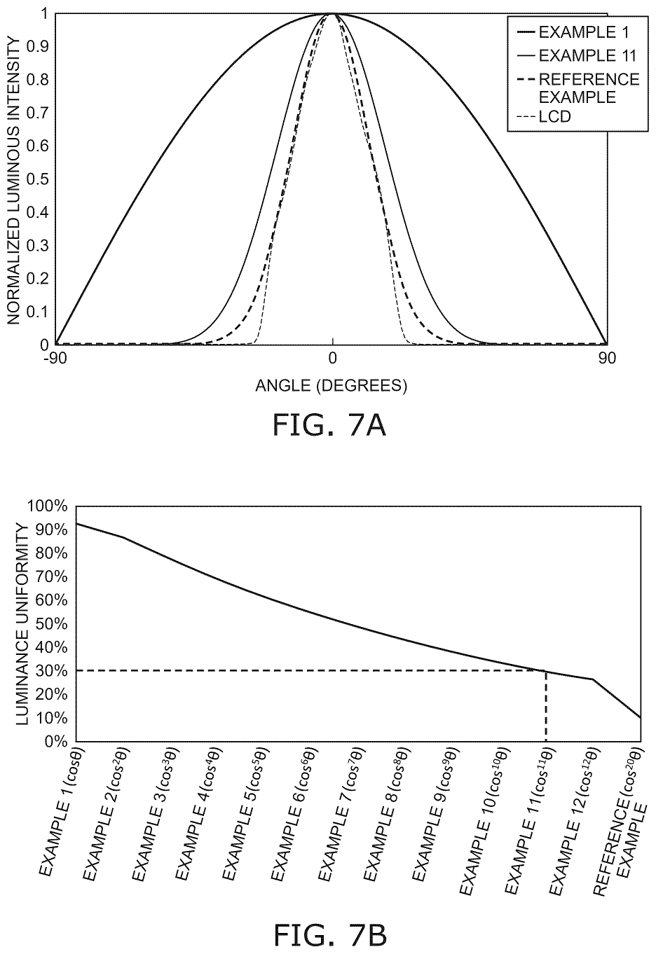

FIG. 7A is a graph showing a light distribution pattern of light emitted from one light-emitting area for examples 1 and 11, the reference example, and an LCD.

FIG. 7B is a graph showing the uniformity of the luminance of the second image for the examples 1 to 12 and the reference example.

The image display systems according to the examples 1 to 12 and the reference example were set in simulation software to include a light source unit and a reflection unit, wherein the light source unit included multiple light-emitting areas arranged in a matrix configuration and an imaging optical system. The light-emitting areas correspond to the pixels 110p of the display device 110 according to the embodiment above.

In FIG. 7A, the horizontal axis is the angle with respect to the optical axis of the light-emitting area, and the vertical axis is the luminous intensity at the angle, normalized by dividing by the luminous intensity at the optical axis, and is a relative value having a maximum value of 1. As shown in FIG. 7A, the display device according to the example 1 was set in the simulation software so that the light emitted from each light-emitting area had a light distribution pattern in which the luminous intensity in the direction of the angle θ′ with respect to the optical axis was represented by cosθ times the luminous intensity at the optical axis. In other words, in the example 1, the light that was emitted from each light-emitting area had an exact Lambertian light distribution.

In the examples 2 to 12, the light that was emitted from each light-emitting area was set in the simulation software to have a light distribution pattern in which the luminous intensity in the direction of the angle θ with respect to the optical axis was represented by cosⁿθ times the luminous intensity at the optical axis. In the example 2, n=2, and n was set to increase by one in order from the example 2 to the example 12.

Also, by investigating the light distribution pattern in one plane of the light emitted from the pixels of an LCD, the light distribution pattern was found to be a light distribution pattern such as that illustrated by the fine broken line of FIG. 7A. Also, as described above, it was found that the luminous intensity in the direction of the angle θ with respect to the optical axis in the light distribution pattern can be approximated by a light distribution pattern represented by cos²⁰θ times the luminous intensity at the optical axis. Therefore, according to the reference example, the luminous intensity in the direction of the angle θ with respect to the optical axis of each light-emitting area was set in the simulation software to have the light distribution pattern represented by cos²⁰θ times the luminous intensity at the optical axis.

The imaging optical systems of the examples 1 to 12 and the reference example each were set to be telecentric at the first image side.

Then, the luminance distribution of the second image formed when the luminance was constant for all light-emitting areas was simulated for the examples 1 to 12 and the reference example. In this case, the second image was a rectangle having a long side of 111.2 mm and a short side of 27.8 mm. Also, in this case, the plane in which the second image was formed was divided into square areas having sides of 1 mm, and the luminance value of each area was simulated.

Also, the uniformity of the luminance of the second image was evaluated for this case. Herein, “the uniformity of the luminance” is the value of the ratio of the minimum value to the maximum value of the luminance in the second image expressed in percent. The results are shown in FIG. 7B. In FIG. 7B, the horizontal axis is the examples and the reference example, and the vertical axis is the uniformity of the luminance.

As shown in FIG. 7B, it was found that the uniformity of the luminance degraded as n increased. This was because the luminance at positions separated from the center of the second image decreased as n increased. In particular, it was found that the uniformity of the luminance was 30% for the example 11, that is, when n=11. It is considered that it is sufficient for the uniformity of the luminance of the second image to be not less than 30% so that the viewer can easily discriminate between the second image and the regions at which the second image is not formed.

Accordingly, it was found that when the imaging optical system is configured to be substantially telecentric, it is preferable for the light emitted from the display device to have a substantially Lambertian light distribution to suppress the uneven luminance of the first and second images. Specifically, it was found that it is preferable for n of cosⁿθ which is the approximation formula of the light distribution pattern to be not more than 11, and more preferably 1. Although the uniformity of the luminance of the second image IM2 degrades as n deviates from 1 as described above, a predetermined luminance distribution can be pre-provided in the display luminance of the display device 110 to compensate for such nonuniformity of the luminance. For example, when the luminance at the outer edge portion of the second image IM2 tends to be less than the luminance at the center portion caused by the light emitted from the pixels 110p of the display device 110 traveling via the imaging optical system 120, the display device 110 may be controlled so that the outputs of the LED elements 112 of the pixels 110p at the outer edge vicinity of the display device 110 are greater than the outputs of the LED elements 112 of the pixels 110p at the center.

### Second Embodiment

A second embodiment will now be described.

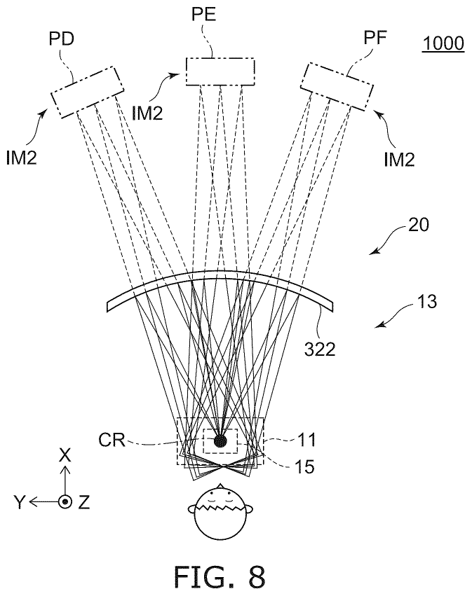

FIG. 8 is a top view showing an image display system according to the embodiment.

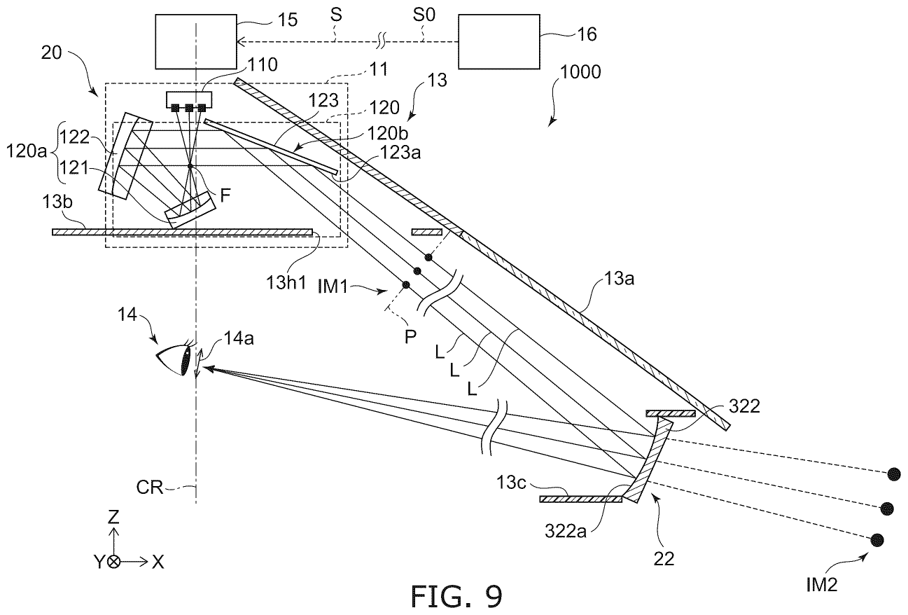

FIG. 9 is an end view showing the image display system according to the embodiment.

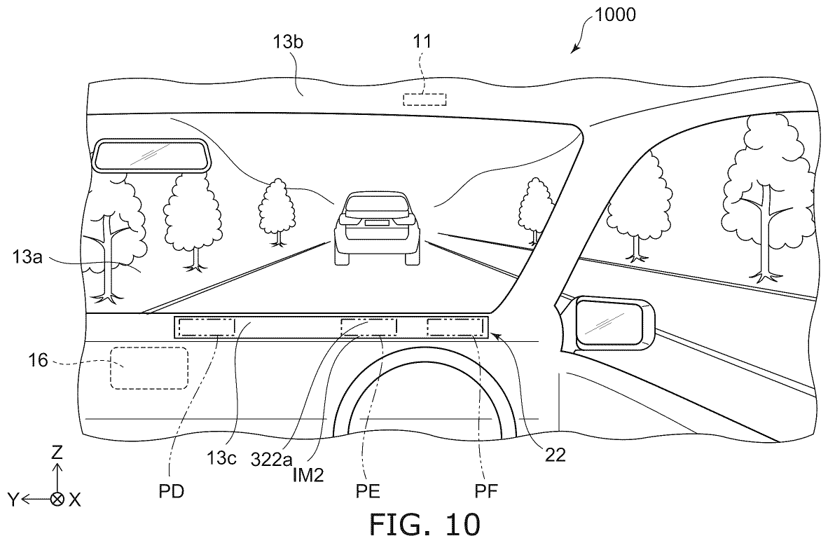

FIG. 10 is a schematic view showing a scenery when viewed by a viewer in a driver's seat.

As shown in FIGS. 8 and 9, the automobile 1000 according to the embodiment includes the vehicle 13, the condition detecting part 16 fixed to the vehicle 13, and the image display system 20 fixed to the vehicle 13. The image display system 20 includes the light source unit 11, the drive unit 15, and a reflection unit 22. The image display system 20 according to the embodiment differs from the image display system 10 according to the first embodiment in that a mirror surface 322a of a mirror 322 of the reflection unit 22 is also used as a reflecting surface causing the viewer 14 to view the second image IM2. In other words, according to the embodiment, the mirror 322 is the projection part.

The configurations of the light source unit 11 and the drive unit 15 of the image display system 20 are the same as or similar to those of the first embodiment. The light source unit 11 is located at the ceiling part 13b of the vehicle 13. The drive unit 15 controls the orientation of the light source unit 11 by moving the light source unit 11 with the axis CR extending in the Z-direction as a rotation axis.

The reflection unit 22 is located at the dashboard part 13c of the vehicle 13. The reflection unit 22 includes the mirror 322. The mirror surface 322a of the mirror 322 is, for example, a concave surface. The mirror surface 322a is arranged at a position and angle facing the eyebox 14a of the viewer 14 when the viewer 14 is in the driver's seat of the vehicle 13. For example, the mirror surface 322a faces a direction between the −X direction (the rearward direction) and the +Z direction (upward direction). The angle of the mirror surface 322a can be finely adjusted according to the position of the eyebox 14a of the viewer 14. Also, a front windshield 13a or a combiner may be used instead of the mirror surface 322a located at the dashboard part 13c as the reflecting surface causing the viewer 14 to view the second image IM2.

Operations of the embodiment will now be described.

The principal rays L that are emitted from the light source unit 11 travel in a direction between the +X direction (the forward direction) and the −Z direction (the downward direction), are reflected by the mirror surface 322a of the mirror 322 of the reflection unit 22, travel in a direction between the −X direction (the rearward direction) and the +Z direction (upward direction), and enter the eyebox 14a of the viewer 14. The path of the principal rays L from the light source unit 11 toward the reflection unit 12 is positioned inward of the front windshield 13a of the vehicle 13 and is substantially along the front windshield 13a. The principal rays L form the first image IM1 at the position P between the light source unit 11 and the reflection unit 22. At this time, the drive unit 15 selects the position at which the first image IM1 is formed by controlling the orientation of the light source unit 11 according to the condition signal S based on the output signal S0 of the condition detecting part 16.

As a result, as shown in FIGS. 8 to 10, the viewer 14 can view the second image IM2, which is a virtual image, depthward of the mirror surface 322a of the dashboard part 13c. The second image IM2 is formed by the mirror surface 322a, and viewed as if a virtual image is distant to, e.g., 3 m beyond, the mirror surface 322a. Therefore, the viewer 14 can view the second image IM2 without greatly moving the focal length of the eyes from the state of viewing the distant scenery via the front windshield 13a. Also, the position at which the second image IM2 is formed is also selected by the drive unit 15 controlling the orientation of the light source unit 11 to select the position at which the first image IM1 is formed. In the example shown in FIGS. 8 and 10, the position is selected from the three positions PD, PE, and PF. The mirror 322 may be one mirror including each of the positions PD, PE, and PF, or may be subdivided into the positions PD, PE, and PF. The curvature of the mirror surface 322a may be uniform, or may be different among the positions PD, PE, and PF.

Effects of the embodiment will now be described.

Similarly to the first embodiment, the image display system 20 according to the embodiment is divided into the two units, the reflection unit 22 and the unit including the light source unit 11 and the drive unit 15, and is located at separate positions in the vehicle 13. Although the image display system 20 needs a long optical path length to make the second image IM2 appear as if the second image IM2 is positioned several meters ahead, by separating the reflection unit 22 from the light source unit 11 and the drive unit 15, a portion of the optical path length can be formed by utilizing the internal space of the vehicle 13. As a result, it is unnecessary to form the necessary optical path length entirely inside the image display system 20, and the image display system 20 can be smaller.

Also, in the image display system 20 according to the embodiment, the reflection unit 22 includes only the mirror 322. As a result, the configuration of the reflection unit 22 can be simplified, and the reflection unit 22 can be smaller. Otherwise, the configuration, operations, and effects according to the embodiment are the same as or similar to those of the first embodiment.

The mirror 322 of the reflection unit 22 may include a half mirror or a transparent plate. In such a case as well, the viewer 14 can be suppressed from undesirably viewing the interior of the dashboard part 13c by making the interior of the dashboard part 13c dark. Alternatively, the mirror surface 322a of the mirror 322 may be made black enough to sufficiently reflect the principal rays L emitted from the light source unit 11. As a result, degradation of the visibility due to external light or the like reflected by the mirror surface 322a of the mirror 322 can be suppressed. Also, the mirror 322 may be arranged to be continuous with the surface of the dashboard part 13c. As a result, it is unnecessary to make a hole in the dashboard part 13c, and the designability of the interior of the automobile 1000 is improved.

It is preferable for the light reflectance of the mirror 322 or the half mirror or transparent plate used instead of the mirror 322 (hereinbelow, called “the mirror 322 and the like”) to be not more than 20%, more preferably not more than 10%, and further more preferably not more than 5%. As a result, the reflection of the sky and/or the ceiling part 13b of the vehicle 13 in the mirror 322 and the like can be suppressed, and the viewer 14 can clearly recognize the second image IM2. For example, the mirror 322 and the like can be achieved by forming an anti-reflection coating on the surface of glass.

By using the mirror surface 322a located at the dashboard part 13c as the reflecting surface, the viewer 14 can reliably view the second image IM2 without being affected by the background of the reflecting surface.

### Third Embodiment

A third embodiment will now be described.

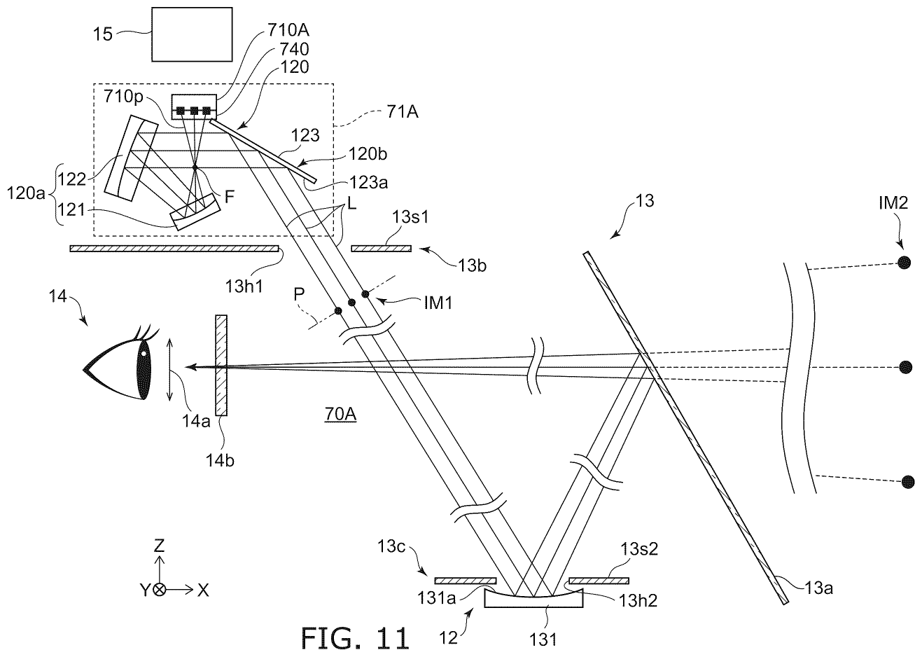

FIG. 11 is an end view showing an image display system according to the embodiment.

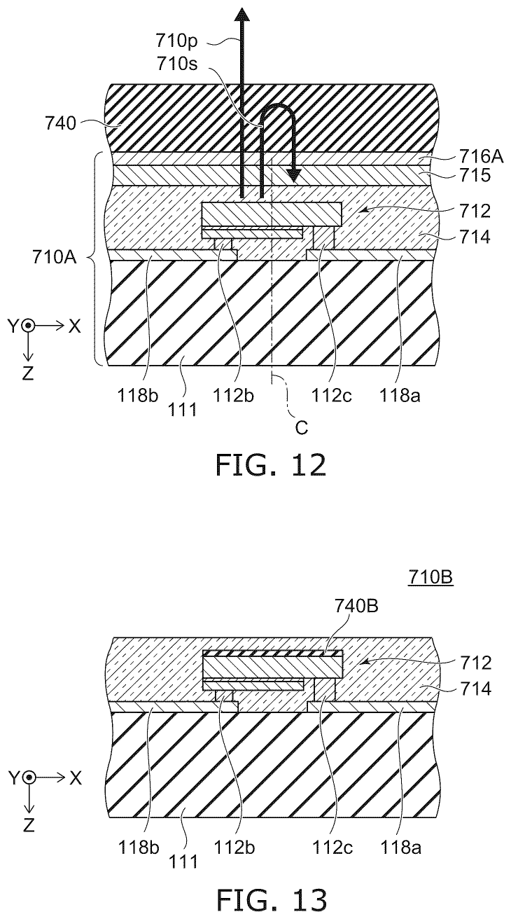

FIG. 12 is an enlarged cross-sectional view showing a portion of the display device and the reflective polarizing element shown in FIG. 11.

As shown in FIGS. 11 and 12, the image display system 70A according to the embodiment differs from the image display system 110 according to the first embodiment in that a display device 710A is included instead of the display device 110, and a reflective polarizing element 740 is further included. The display device 710A according to the embodiment differs from the display device 110 according to the first embodiment in that the light-emitting surface of the LED element 712 is substantially flat, and a protective layer 714, a wavelength conversion member 715, and a light-scattering member 716A are further included. Otherwise, the configuration of the display device 710A is the same as or similar to that of the display device 110 according to the first embodiment. Also, similarly to the image display system 10 according to the first embodiment, the image display system 70A according to the embodiment includes the drive unit 15.

The protective layer 714 covers multiple LED elements 712 arranged in a matrix configuration. The protective layer 714 can include, for example, a light-transmitting material such as a polymer material that includes a sulfur (S)-including substituent group or a phosphorus (P) atom-including group, a high refractive index nanocomposite material in which inorganic nanoparticles having a high refractive index are added to a polymer matrix of polyimide, etc.

The wavelength conversion member 715 is located on the protective layer 714. The wavelength conversion member 715 includes one or more types of wavelength conversion materials such as a general phosphor material, a perovskite phosphor material, a quantum dot (Quantum Dot: QD), etc. The light that is emitted from each LED element 712 is incident on the wavelength conversion member 715. The wavelength conversion material that is included in the wavelength conversion member 715 emits light of a light emission peak wavelength different from the light emission peak wavelength of the LED element 712 by the light from the LED element 712 being incident on the wavelength conversion material. The light that is emitted by the wavelength conversion member 715 has a substantially Lambertian light distribution.

The light-scattering member 716A includes, for example, a light-transmitting resin member, and light-scattering particles or voids located inside the resin member. Examples of the resin member include, for example, polycarbonate, etc. Examples of the light-scattering particles include, for example, materials having a refractive index difference with the resin member such as titanium oxide, etc. A light scattering effect may be obtained by providing an unevenness in the surface of the light-scattering member 716A by surface roughening.

For example, a multilayer stacked thin film polarizing plate in which thin film layers having different polarization characteristics are stacked, etc., can be used as the reflective polarizing element 740. The reflective polarizing element 740 is located on the display device 710A. According to the embodiment, the reflective polarizing element 740 is located on the light-scattering member 716A. Therefore, the light that is emitted from the LED element 712 and the wavelength conversion member 715 is incident on the reflective polarizing element 740. The reflective polarizing element 740 transmits a first polarized light 710p of the light emitted from the display device 710A and reflects a second polarized light 710s toward the display device 710A. The oscillation direction of the electric field of the second polarized light 710s is substantially orthogonal to the oscillation direction of the electric field of the first polarized light 710p.

According to the embodiment, the first polarized light 710p is P-polarized light, and the second polarized light 710s is S-polarized light. Herein, “P-polarized light” means light of which the oscillation direction of the electric field is substantially parallel to the XY-plane. Also, “S-polarized light” means light of which the oscillation direction of the electric field is substantially perpendicular to the XY-plane including the incident light and the reflected light.

There are cases where the viewer 14 driving the vehicle 13 wears polarized sunglasses 14b to reduce glare such as sunlight reflected by a puddle or the like in front of the vehicle 13 and transmitted by the front windshield 13a, etc. In such a case, the component corresponding to the P-polarized light of the sunlight reflected by the puddle or the like when viewed from the front windshield 13a is particularly reduced, therefore, the polarized sunglasses 14b are designed to shield the greater part of the S-polarized light. Accordingly, when the viewer 14 wears the polarized sunglasses 14b, there is a possibility that the second image IM2 may be difficult for the viewer 14 to view because the polarized sunglasses 14b undesirably shield the greater part of the S-polarized light included in the light emitted by the display device 710A. In the specification, P-polarized light and S-polarized light are physically defined by reflection objects such as the puddles and the like described above.

According to the embodiment, the reflective polarizing element 740 transmits the first polarized light 710p and reflects the second polarized light 710s of the light emitted from the display device 710A. After traveling via the imaging optical system 120, the reflection unit 12, and the inner surface of the front windshield 13a, the greater part of the first polarized light 710p transmitted by the reflective polarizing element 740 enters the eyebox 14a without being shielded by the polarized sunglasses 14b. The incidence angle of the first polarized light 710p when incident on the inner surface of the front windshield 13a is set to a different angle from Brewster's angle.

Specifically, as shown in FIG. 12, the light that is emitted from the LED element 712 is irradiated on the wavelength conversion member 715. As a result, the wavelength conversion member 715 is excited and emits light of a light emission peak wavelength longer than the light emission peak wavelength of the light emitted from the LED element 712. According to the embodiment, the light that is emitted from the display device 710A includes light emitted from the LED element 712 and light emitted from the wavelength conversion member 715. Hereinbelow, the light that is emitted from the display device 710A and emitted from the LED element 712 also is called “short-wavelength light”, and the light that is emitted from the display device 710A and emitted from the wavelength conversion member 715 also is called “long-wavelength light”. However, the greater part of the light emitted from the LED element 712 may be absorbed by the wavelength conversion member 715.

The greater part of the first polarized light 710p included in the short-wavelength and long-wavelength light is transmitted through the reflective polarizing element 740 and emitted from the imaging optical system 120. Also, the greater part of the second polarized light 710s included in the short-wavelength and long-wavelength light is reflected by the reflective polarizing element 740. Scattering reflection of a portion of the second polarized light 710s reflected by the reflective polarizing element 740 is performed by components of the display device 710A such as the light-scattering member 716A, the wavelength conversion member 715, etc. A portion of the second polarized light 710s is converted into the first polarized light 710p by the scattering reflection. A portion of the first polarized light 710p converted from the second polarized light 710s is transmitted through the reflective polarizing element 740 and emitted from a light source unit 71A. Therefore, the luminance of the first image IM1 can be increased while increasing the ratio of the first polarized light 710p included in the light emitted from the light source unit 71A. By improving the luminance of the first image IM1, the luminance of the second image IM2 also is improved. As a result, the viewer 14 easily views the second image IM2.

Also, a portion of the short-wavelength light included in the second polarized light 710s may be reflected by the reflective polarizing element 740 and then incident on the wavelength conversion member 715. In such a case, an effect can be expected in which the wavelength conversion member 715 absorbs the short-wavelength light of the second polarized light 710s and additionally radiates long-wavelength light. Both the scattered reflection light and the radiated light have substantially Lambertian light distributions. Also, the reflective polarizing element 740 itself may perform scattering reflection of the second polarized light 710s. In such a case as well, a portion of the second polarized light 710s is converted into the first polarized light 710p by the scattering reflection.

According to the embodiment, one reflective polarizing element 740 covers all of the pixels of the display device 710A. However, the light source unit may include multiple reflective polarizing elements, and the reflective polarizing elements may be located respectively on the pixels. Also, the configuration of the display device used in combination with the reflective polarizing element is not limited to the configuration described above. For example, the display device may be configured without a light-scattering member by using the light scattering reflection effect of the wavelength conversion member. Also, the display device may be configured without a wavelength conversion member by using the scattering reflection effect of the light-scattering member. Also, the display device may be configured without either a wavelength conversion member or a light-scattering member by using the light scattering reflection effect of multiple recessed portions or multiple protrusions provided in the light-emitting surface of the LED element as in the first embodiment.

Effects of the embodiment will now be described.

The light source unit 71A according to the embodiment further includes the reflective polarizing element 740 that is located on the display device 710A, transmits the first polarized light 710p of the light emitted from the display device 710A, and reflects the second polarized light 710s of the light emitted from the display device 710A. Therefore, the luminance of the first image IM1 can be increased while increasing the ratio of the first polarized light 710p included in the light emitted from the light source unit 71A.

Also, the light that is emitted from the reflective polarizing element 740 has a substantially Lambertian light distribution. Therefore, according to the embodiment as well, the light source unit 71A that is compact and can form the high-quality first image IM1 can be provided. Because the multiple LED elements 712 are discretely mounted on the substrate 111, the first image IM1 may have a grainy appearance. The wavelength conversion member 715 has the effect of relaxing the grainy appearance. The light-scattering member 716A can further reinforce the effect of suppressing the grainy appearance. Otherwise, the configuration, operations, and effects according to the embodiment are the same as or similar to those of the first embodiment.

### Modification of Third Embodiment

A modification of the third embodiment will now be described.

FIG. 13 is an end view showing a display device according to the modification.

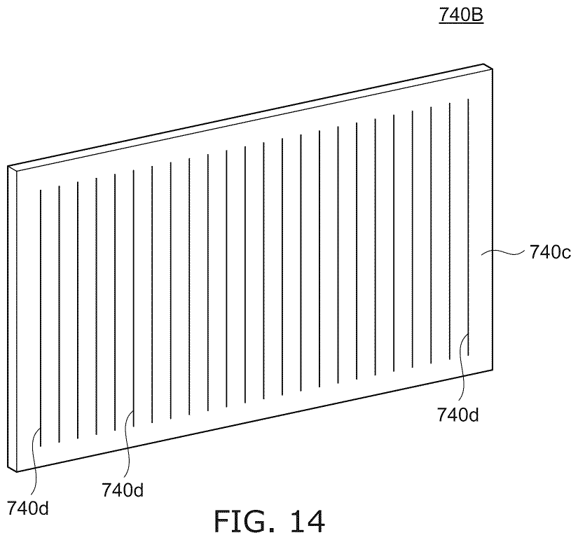

FIG. 14 is a perspective view showing a reflective polarizing element according to the modification.

As shown in FIG. 13, the display device 710B according to the modification differs from the display device 710A according to the third embodiment in that a reflective polarizing element 740B is included instead of the reflective polarizing element 740. The reflective polarizing element 740B is located on the LED element 712 and contacts the LED element 712.

As shown in FIG. 14, the reflective polarizing element 740B is a wire grid polarizing plate. In the reflective polarizing element 740B, multiple metal wires 740d are arranged at uniform spacing parallel to each other on a transparent resin film 740c. As a result, the reflective polarizing element 740B transmits the first polarized light 710p of the light emitted from the LED element 712, and reflects the second polarized light 710s of the light emitted from the LED element 712 to return the second polarized light 710s to the LED element 712. Otherwise, the configuration, operations, and effects according to the modification are the same as or similar to those of the third embodiment.

### Fourth Embodiment

A fourth embodiment will now be described.

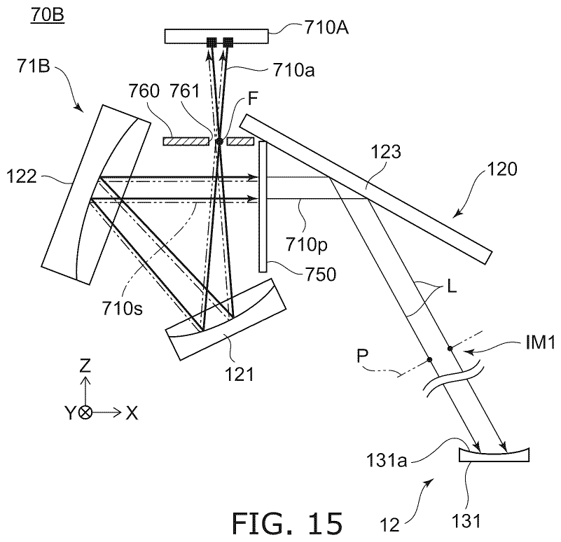

FIG. 15 is a side view showing a light source unit according to the embodiment.

As shown in FIG. 15, an image display system 70B according to the embodiment differs from the image display system 10 according to the first embodiment in that a light source unit 71B includes the display device 710A having a configuration same as or similar to that of the third embodiment instead of the display device 110, and a reflective polarizing element 750 and a light-shielding member 760 are further included. In FIG. 15, only the light-shielding member 760 is shown in cross section.

The reflective polarizing element 750 can include, for example, a wire-grid reflective polarizing element using multiple metal nanowires. The reflective polarizing element 750 is located in a part of the optical path from the display device 710A to the reflection unit 12 at which the multiple principal rays L are substantially parallel to each other. According to the embodiment, the multiple principal rays L are substantially parallel to each other in the optical path between the intermediate element 122 and the reflection unit 12, and the reflective polarizing element 750 is located between the intermediate element 122 and the output element 123.

The reflective polarizing element 750 transmits the first polarized light 710p, which is P-polarized light, and reflects the second polarized light 710s, which is S-polarized light, to return the second polarized light 710s to the display device 710A. Specifically, the display device 710A emits light 710a that includes the first and second polarized lights 710p and 710s. The light 710a travels via the input element 121 and the intermediate element 122 and then is incident on the reflective polarizing element 750.

The reflective polarizing element 750 transmits the greater part of the first polarized light 710p included in the light 710a. The greater part of the first polarized light 710p transmitted through the reflective polarizing element 750 travels via the output element 123 and then is emitted from the reflection unit 12.

The reflective polarizing element 750 reflects the greater part of the second polarized light 710s included in the light 710a and returns the greater part of the second polarized light 710s along the optical path from the display device 710A to the reflective polarizing element 750. Specifically, the reflective polarizing element 750 has a flat plate shape. The reflective polarizing element 750 is arranged to be substantially orthogonal to the principal rays L. The reflective polarizing element 750 specularly reflects the greater part of the second polarized light 710s. Therefore, the greater part of the second polarized light 710s reflected by the reflective polarizing element 750 travels via the intermediate element 122 and the input element 121 in this order and then returns to the display device 710A.

Scattering reflection of a portion of the second polarized light 710s returning to the display device 710A is performed by components of the display device 710A such as the light-scattering member 716A, the wavelength conversion member 715, etc. A portion of the second polarized light 710s is converted into the first polarized light 710p by the scattering reflection. A portion of the first polarized light 710p converted from the second polarized light 710s travels via the input element 121 and the intermediate element 122 and then is transmitted through the reflective polarizing element 750. The greater part of the first polarized light 710p transmitted through the reflective polarizing element 750 travels via the output element 123 and then is emitted from the reflection unit 12. Therefore, the luminance of the second image IM2 can be increased while increasing the ratio of the first polarized light 710p included in the light emitted from the image display system 70B. As a result, the viewer 14 easily views the second image IM2.

Also, similarly to the eleventh embodiment, a portion of the short-wavelength light included in the second polarized light 710s returning to the display device 710A may be irradiated on the wavelength conversion member 715. In such a case as well, similarly to the eleventh embodiment, the wavelength conversion member 715 absorbs the short-wavelength light of the second polarized light 710s, and an effect of additionally radiating long-wavelength light can be expected.

The light-shielding member 760 is located between the display device 710A and the input element 121 of the imaging optical system 120. For example, the light-shielding member 760 has a flat plate shape substantially parallel to the XY-plane. An aperture 761 that extends through the light-shielding member 760 in the Z-direction is provided in the light-shielding member 760. The focal point F of the imaging optical system 120 is positioned inside the aperture 761.

The light emitted from the display device 710A and passing through the focal point F and the vicinity of the focal point F passes through the aperture 761 of the light-shielding member 760 and is incident on the input element 121, and the greater part of the light other than the light passing through the aperture 761 is shielded by the light-shielding member 760. Also, the second polarized light 710s that is reflected by the reflective polarizing element 750 and travels along the optical path, i.e., the light that passes through the focal point F and the vicinity of the focal point F, passes through the aperture 761 of the light-shielding member 760 and returns to the display device 710A. On the other hand, the greater part of the second polarized light 710s that is reflected by the reflective polarizing element 750 and travels toward the display device 710A and not along the optical path is shielded by the light-shielding member 760.

Effects of the embodiment will now be described.

The image display system 70B according to the embodiment further includes the reflective polarizing element 750. The reflective polarizing element 750 is located at a part of the optical path from the display device 710A to the reflection unit 12 at which the multiple principal rays L that are emitted from mutually-different positions of the display device 710A and pass through the first image IM1 are substantially parallel to each other, transmits the first polarized light 710p of the light emitted from the display device 710A, and reflects the second polarized light 710s of the light emitted from the display device 710A to return the second polarized light 710s to the display device 710A. Therefore, the luminance of the second image IM2 can be increased while increasing the ratio of the first polarized light 710p included in the light emitted from the image display system 70B.

Also, the light-shielding member 760 is located between the display device 710A and the input element 121. The aperture 761 through which the second polarized light 710s returning to the display device 710A along the optical path passes is provided in the light-shielding member 760. Therefore, the second polarized light 710s that is reflected by the reflective polarizing element 750, does not travel along the optical path, and becomes stray light can be suppressed from traveling toward the display device 710A while allowing the second polarized light 710s that is reflected by the reflective polarizing element 750 and travels along the optical path to return to the display device 710A. The quality of the first and second images IM1 and IM2 can be increased thereby. Also, there is a case in which the light that is emitted from the display device 710A, does not travel along the optical path, and becomes stray light is reflected by the reflective polarizing element 750 and/or optical elements of the imaging optical system 120, and travels toward the display device 710A. The light-shielding member 760 can suppress such stray light from being re-excited and/or scattered and reflected at unexpected locations.

The image display system 70B may not include the light-shielding member 760. Also, the reflective polarizing element 740 described in the third embodiment may further be provided on the display device 710A of the image display system 70B. In such a case, the second polarized light 710s that could not be reflected by the reflective polarizing element 740 on the display device 710A can be reflected by the reflective polarizing element 750. Therefore, the luminance of the second image IM2 can be increased while increasing the ratio of the first polarized light 710p included in the light emitted from the image display system 70B. Otherwise, the configuration, operations, and effects according to the embodiment are the same as or similar to those of the third embodiment.

### Modification of Fourth Embodiment

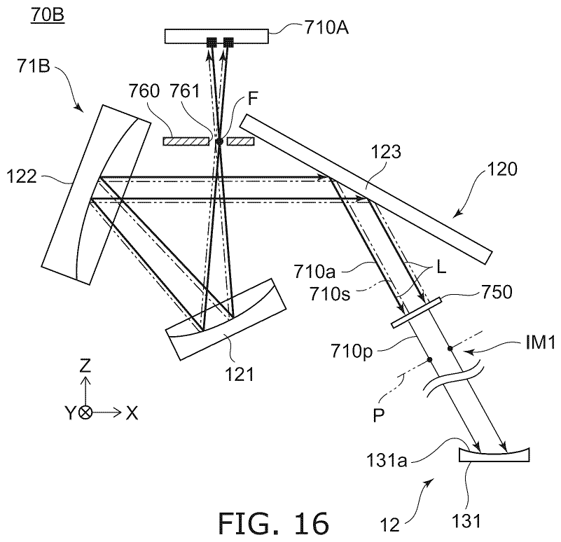

A modification of the fourth embodiment will now be described. FIG. 16 is a side view showing a light source unit according to the modification.

In FIG. 16 as well, only the light-shielding member 760 is shown in cross section.

According to the modification as shown in FIG. 16, the reflective polarizing element 750 is located between the output element 123 and the reflection unit 12. Although an example is shown in FIG. 16 in which the reflective polarizing element 750 is positioned between the output element 123 and the first image IM1, the reflective polarizing element 750 may be located between the first image IM1 and the reflection unit 12. Otherwise, the configuration, operations, and effects according to the modification are the same as or similar to those of the fourth embodiment.

Embodiments and their modifications described above are examples embodying the invention, and the invention is not limited to these embodiments and their modifications. For example, additions, deletions, or modifications to some of the components or processes of the embodiments and modifications described above also are included in the invention. Also, the embodiments and modifications described above can be implemented in combination with each other.

Embodiments include the following aspects.

### Note 1

An image display system, comprising:
a light source unit including
   a display device configured to display an image,
   an imaging optical system configured to display an image beyond a projection part when viewed by a viewer by projecting a first image corresponding to the image toward the projection part, the image being visible to the viewer; and
a drive unit modifying a position of the first image by controlling a position and/or an orientation of the light source unit based on a condition signal input from outside.

### Note 2

The image display system according to note 1, wherein
the image display system is mounted in a vehicle, and
the drive unit controls an orientation of the light source unit with respect to an axis extending in a vertical direction of the vehicle as a rotation axis.

Note 3

The image display system according to note 2, wherein
the condition signal indicates a travel direction of the vehicle, and
the drive unit sets a projection direction of the first image by the light source unit to a direction corresponding to the travel direction.

### Note 4

The image display system according to note 2, wherein
the condition signal indicates a direction of a line of sight of a driver of the vehicle, and
the drive unit sets a projection direction of the first image by the light source unit to a direction corresponding to the direction of the line of sight.

### Note 5

The image display system according to note 2, wherein the condition signal indicates a direction toward an object outside the vehicle, and
the drive unit sets a projection direction of the first image by the light source unit to a direction corresponding to the direction toward the object outside the vehicle.

### Note 6

The image display system according to any one of notes 1 to 5, wherein
the projection part is a mirror or a semi-transmissive mirror.

### Note 7

The image display system according to any one of notes 2 to 5, wherein
the projection part is a front windshield of the vehicle.

### Note 8

The image display system according to any one of notes 1 to 7, wherein
the imaging optical system includes:
   an input element on which light emitted from the display device is incident; and
   an output element on which light traveling via the input element is incident,
light emitted from the output element forms the first image,
the imaging optical system is substantially telecentric at the first image side, and
the light emitted from the display device has a substantially Lambertian light distribution.

### Note 9

The image display system according to note 8, wherein
the light emitted from the display device has a light distribution pattern in which a luminous intensity in a direction of an angle θ with respect to an optical axis of the light emitted from the display device is approximated by cosⁿθ times a luminous intensity at the optical axis, and
n is a value greater than 0.

### Note 10

The image display system according to note 9, wherein
n is not more than 11.

### Note 11

The image display system according to any one of notes 1 to 10, wherein
the display device is an LED display, and
the LED display includes a plurality of LED elements.

### Note 12

The image display system according to note 11, wherein
light emitted from the LED element has a substantially Lambertian light distribution.

### Note 13

The image display system according to note 11 or 12, wherein
the display device further includes a wavelength conversion member located on the LED element, and
light emitted from the LED element is incident on the wavelength conversion member.

### Note 14

The image display system according to any one of notes 1 to 13, wherein
the imaging optical system includes a direction modifying part including a bending part and the output element,
the bending part includes the input element,
the bending part bends a plurality of principal rays,
the plurality of principal rays are emitted from mutually-different positions of the display device, crosses each other before being incident on the input element, and reaches the first image,
the bending part bends the plurality of principal rays to be substantially parallel to each other before and after the first image, and
the direction modifying part modifies a travel direction of the plurality of principal rays so that the plurality of principal rays traveling via the bending part are directed toward a formation position of the first image.

### Note 15

The image display system according to any one of notes 1 to 14, wherein
the light source unit further includes a light-shielding member located between the display device and the imaging optical system,
an aperture is provided in the light-shielding member,
a portion of light from the display device toward the imaging optical system passes through the aperture, and
another portion of the light from the display device toward the imaging optical system is shielded by the light-shielding member.

### Note 16

The image display system according to any one of notes 1 to 15, further comprising:
a reflection unit separated from the light source unit,
the reflection unit reflecting light emitted from the imaging optical system,
the first image being formed between the light source unit and the reflection unit.

### Note 17

The image display system according to note 16, further comprising:
a reflective polarizing element located in an optical path from the display device to the reflection unit,
the reflective polarizing element transmitting a first polarized light of light emitted from the display device,
the reflective polarizing element reflecting a second polarized light of the light emitted from the display device so that the second polarized light returns to the display device.

### Note 18

The image display system according to note 17, wherein
the reflective polarizing element is located in a part of the optical path from the display device to the reflection unit,
a plurality of principal rays are emitted from mutually-different positions of the display device, passes through the first image, and is substantially parallel to each other at the part of the optical path.

### Note 19

An automobile, comprising:
the image display system according to any one of notes 2 to 18;
the vehicle; and
a condition detecting part detecting a condition inside or outside the vehicle,
the image display system being fixed to the vehicle.

### INDUSTRIAL APPLICABILITY

For example, the invention can be utilized in a head-up display.

### REFERENCE NUMERAL LIST

10, 20, 70A, 70B image display system
11, 71A, 71B light source unit
12 reflection unit
13 vehicle
13a front windshield
13b ceiling part
13c dashboard part
13h1, 13h2 through-hole
13s1, 13s2 wall
14 viewer
14a eyebox
14b polarized sunglasses
15 drive unit
16 condition detecting part
20 image display system
22 reflection unit
110 display device
110p pixel
111 substrate
112 LED element
112a semiconductor stacked body
112b anode electrode
112c cathode electrode
112p1 p-type semiconductor layer
112p2 active layer
112p3 n-type semiconductor layer
112s light-emitting surface
112t recessed portion
118a wiring part
120, 2120 imaging optical system
120a bending part
120b direction modifying part
121 input element
121a mirror surface
122 intermediate element
122a mirror surface
123 output element
123a mirror surface
131 mirror
131 a mirror surface
322 mirror
322a mirror surface
710, 710A, 710B display device
710a light
712 LED element
712p3 n-type semiconductor layer
714 protective layer
715 wavelength conversion member
716A light-scattering member
740 reflective polarizing element
740B reflective polarizing element
740c resin film
740d metal wire
750 reflective polarizing element
760 light-shielding member
761 aperture
1000 automobile
2011 light source unit
2110 display device
2110p pixel
2110s light-emitting surface
C optical axis
CR axis
F focal point
IM1 first image
IM2 second image
L principal ray
P formation position
PA, PB, PC, PD, PE, PF position
S condition signal
S0 output signal
a1, a2 point
θ angle

1. An image display system, comprising:
a light source unit comprising:
a display device configured to display an image, and
an imaging optical system configured to project a first image corresponding to the image toward the projection part, and to thereby display a second image, which is a virtual image visible to a viewer as being located beyond the projection part; and
a drive unit configured to modify a position of the first image by controlling a position and/or an orientation of the light source unit based on a condition signal.

2. The image display system according to claim 1, wherein:
the image display system is mounted in a vehicle; and
the drive unit is configured to control an orientation of the light source unit with respect to an axis extending in a vertical direction of the vehicle as a rotation axis.

3. The image display system according to claim 2, wherein:
the condition signal indicates a travel direction of the vehicle; and
the drive unit is configured to set a projection direction of the first image by the light source unit to a direction corresponding to the travel direction.

4. The image display system according to claim 2, wherein:
the condition signal indicates a direction of a line of sight of a driver of the vehicle; and
the drive unit is configured to set a projection direction of the first image by the light source unit to a direction corresponding to the direction of the line of sight.

5. The image display system according to claim 2, wherein:
the condition signal indicates a direction toward an object outside the vehicle; and
the drive unit is configured to set a projection direction of the first image by the light source unit to a direction corresponding to the direction toward the object outside the vehicle.

6. The image display system according to claim 1, wherein:
the projection part is a mirror or a semi-transmissive mirror.

7. The image display system according to claim 2, wherein:
the projection part is a front windshield of the vehicle.

8. The image display system according to claim 1, wherein:
the imaging optical system comprises:
an input element on which light emitted from the display device is incident, and
an output element on which light traveling via the input element is incident;
light emitted from the output element forms the first image;
the imaging optical system is substantially telecentric at the first image side; and
the light emitted from the display device has a substantially Lambertian light distribution.

9. The image display system according to claim 8, wherein:
the light emitted from the display device has a light distribution pattern in which a luminous intensity in a direction of an angle θ with respect to an optical axis of the light emitted from the display device is approximated by cosⁿθ times a luminous intensity at the optical axis, where n is a value greater than 0.

10. The image display system according to claim 9, wherein:
n is not more than 11.

11. The image display system according to claim 1, wherein:
the display device is an LED display; and
the LED display includes a plurality of LED elements.

12. The image display system according to claim 11, wherein:
light emitted from the LED element has a substantially Lambertian light distribution.

13. The image display system according to claim 11, wherein:
the display device further comprises a wavelength conversion member located on the LED element; and
light emitted from the LED element is incident on the wavelength conversion member.

14. The image display system according to claim 1, wherein:
the imaging optical system comprises a direction modifying part comprises a bending part and the output element;
the bending part comprises the input element;
the bending part is configured to bend a plurality of principal rays;
the plurality of principal rays are emitted from mutually-different positions of the display device, each other before being incident on the input element, and reach the first image;
the bending part is configured to bend the plurality of principal rays to be substantially parallel to each other before and after the first image; and
the direction modifying part is configured to modify a travel direction of the plurality of principal rays so that the plurality of principal rays traveling via the bending part are directed toward a formation position of the first image.

15. The image display system according to claim 1, wherein:
the light source unit further comprises a light-shielding member located between the display device and the imaging optical system;
the light-shielding member comprises an aperture;
a portion of light from the display device toward the imaging optical system passes through the aperture; and
another portion of the light from the display device toward the imaging optical system is shielded by the light-shielding member.

16. The image display system according to claim 1, further comprising:
a reflection unit separated from the light source unit;
the reflection unit reflecting light emitted from the imaging optical system; and
the first image is formed between the light source unit and the reflection unit.

17. The image display system according to claim 16, further comprising:
a reflective polarizing element located in an optical path from the display device to the reflection unit; wherein:
the reflective polarizing element is configured to transmit first polarized light of light emitted from the display device; and
the reflective polarizing element is configured to reflect second polarized light of the light emitted from the display device so that the second polarized light returns to the display device.

18. The image display system according to claim 17, wherein:
the reflective polarizing element is located in a part of the optical path from the display device to the reflection unit; and
a plurality of principal rays are emitted from mutually-different positions of the display device, pass through the first image, and are substantially parallel to each other at the part of the optical path.

19. An automobile, comprising:
the image display system according to claim 2;
the vehicle; and
a condition detecting part configured to detect a condition inside or outside the vehicle; wherein
the image display system is fixed to the vehicle.
